(19) United States
(12) Patent Application Publication
(10) Pub. No.: US 2026/0015724 A1
(43) Pub. Date: Jan. 15, 2026

(54) THIN FACEPLATE DESIGN FOR USE IN A PROCESSING CHAMBER

(71) Applicant: Applied Materials, Inc., Santa Clara, CA (US)

(72) Inventors: Tuan Anh NGUYEN, San Jose, CA (US); Juan C. ROCHA, San Carlos, CA (US)

(21) Appl. No.: 18/768,923

(22) Filed: Jul. 10, 2024

(51) Int. Cl. C23C 16/455; C23C 16/458

(52) U.S. Cl. CPC C23C 16/45591; C23C 16/458

(57) ABSTRACT

Embodiments of the present disclosure generally relate to a faceplate including a thermal expansion section for use in a semi-conductor processing chamber. In one or more embodiments, a faceplate for a process chamber includes an inner section. The inner section includes a plurality of apertures. The faceplate further includes an outer section having a ring shape. The outer section surrounds the inner section. The faceplate further includes a thermal expansion section having a thickness less than a thickness of the inner section and a thickness the outer section. The thermal expansion section connects the inner section and the outer section. The thermal expansion section is configured to deform when the inner section expands.

### BACKGROUND

### FIELD

Embodiments of the present disclosure generally relate to a faceplate including a thermal expansion section for use in a semi-conductor processing chamber.

### DESCRIPTION OF THE RELATED ART

Faceplates are commonly used in semiconductor processing chambers in order to aid in the deposition process. The faceplate helps disperse the precursor gases during the deposition process. The faceplate is often formed of aluminum and contains a plurality of holes drilled through the faceplate to help distribute the precursor gases. The faceplate may also act as either a “hot” electrode or a ground electrode to ignite a plasma during the deposition process. The faceplate is often subject to elevated temperatures, such as 200 degrees Celsius or greater, during the deposition process. This elevated temperature often causes the faceplate bow or buckle due to thermal expansion which can inhibit the deposition process.

In order to help limit the deformation of the faceplate due to the thermal expansion, conventional faceplates are designed to be relatively thick, usually having a thickness of 25 mm or more. In order to drill the holes in a faceplate with such a high thickness, multiple drill passes are required to drill each hole. A single faceplate can include thousands of holes, so having to conduct multiple passes greatly increases the time and cost for manufacturing a faceplate.

Thus, there is a need for an improved faceplate.

### SUMMARY

Embodiments of the present disclosure generally relate to a faceplate including a thermal expansion section for use in a semi-conductor processing chamber.

In one or more embodiments, a faceplate for a process chamber includes an inner section. The inner section includes a plurality of apertures. The faceplate further includes an outer section having a ring shape. The outer section surrounds the inner section. The faceplate further includes a thermal expansion section having a thickness less than a thickness of the inner section and a thickness the outer section. The thermal expansion section connects the inner section and the outer section. The thermal expansion section is configured to deform when the inner section expands.

A lid assembly for a process chamber includes a gas box and a gas conduit passing through the gas box. The lid assembly further includes a blocker plate coupled to the gas box a faceplate. The faceplate includes an inner section, including a plurality of apertures, and an outer section having a ring shape. The faceplate further includes a thermal expansion section having a thickness less than a thickness of the inner section and a thickness the outer section. The thermal expansion section connects the inner section and the outer section. The thermal expansion section is configured to deform when the inner section expands.

In one or more embodiments, a processing chamber includes a substrate support assembly disposed within a processing volume of the process chamber, a chamber wall; and a lid assembly coupled to the chamber wall. The lid assembly includes a blocker plate and a faceplate coupled to the blocker plate. The faceplate includes an inner section, including a plurality of apertures, an outer section having a ring shape coupled to the chamber wall, and a thermal expansion section. The thermal expansion section has thickness less than a thickness of the inner section and a thickness the outer section. The thermal expansion section connects the inner section and the outer section. The thermal expansion section is configured to deform when the inner section expands.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 is a schematic cross-section of a process chamber, according to one or more embodiments.

FIG. 2A is a schematic illustration of a cross-section of the faceplate shown in FIG. 1, according to one or more embodiments.

FIG. 2B is an enlarged schematic illustration of a section of the faceplate shown in FIG. 2A, according to one or more embodiments.

FIG. 3 is a schematic top view of the faceplate shown in FIG. 2A, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a faceplate including a thermal expansion section for use in a semi-conductor processing chamber.

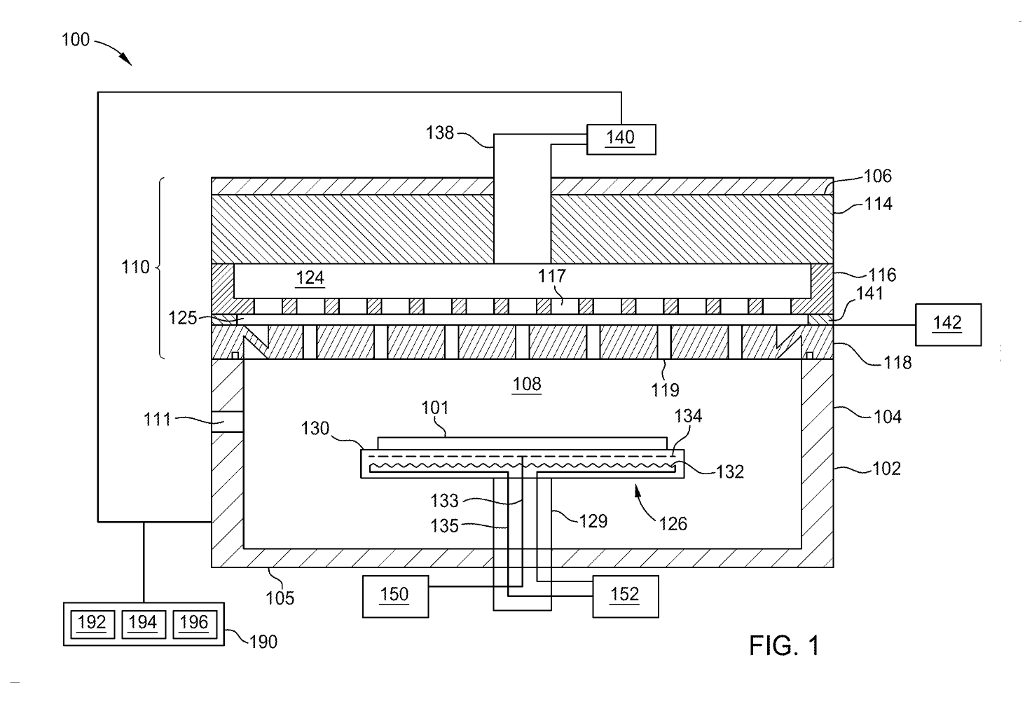

FIG. 1 is a schematic cross-section of a process chamber 100, according to one or more embodiments. The process chamber 100 includes a chamber body 102 having sidewalls 104, a bottom 105, and a lid assembly 110. The sidewalls 104 and faceplate 118 of the lid assembly 110 define a processing volume 108. A substrate transfer port 111 may be formed in the sidewall 104 for transferring substrates into and out of the processing volume 108. The process chamber 100 may be of one a chemical vapor deposition (CVD) process chamber, an atomic layer deposition (ALD) process chamber, a metalorganic chemical vapor deposition (MOCVD) process chamber, a plasma-enhanced chemical vapor deposition (PECVD) process chamber, and a plasma-enhanced atomic layer deposition (PEALD) process chamber, among others.

A substrate support assembly 126 is disposed within the processing volume 108 of the process chamber 100 below the lid assembly 110. The substrate support assembly 126 is configured to support a substrate 101 during processing. The substrate 101 may have a circular circumference. The substrate support assembly 126 may include a plurality of lift pins (not shown) movably disposed therethrough. The lift pins may be actuated to project from a surface 130 of the substrate support assembly 126, thereby placing the substrate 101 in a spaced-apart relation to the substrate support assembly 126 to facilitate transfer with a transfer robot (not shown) through the substrate transfer port 111. The substrate support assembly 126 is coupled to the shaft 129 to facilitate vertical actuation and/or rotation of the substrate support assembly 126.

An electrode 134 is part of the substrate support assembly 126. The electrode 134 is embedded within the substrate support assembly 126 or coupled to the surface 130 of the substrate support assembly 126. The electrode 134 may be a plate, a perforated plate, a mesh, a wire screen, or any other distributed arrangement. The electrode 134 is a tuning electrode, and is coupled to a power supply 150 by a conduit 133 disposed in the shaft 129 of the substrate support assembly 126.

An electrode 132, which may be a bias electrode and/or an electrostatic chucking electrode, may be part of the substrate support assembly 126. The electrode 132 may be coupled to a power supply 152 via conduit 135. The power supply 152 may be direct current (DC) power, pulsed DC power, radio frequency (RF) power, pulsed RF power, or a combination thereof.

The lid assembly 110 includes a lid 106, a gas box 114, a blocker plate 116, and a faceplate 118. A plenum 124 is formed between the gas box 114 and the blocker plate 116. Further, a plenum 125 is formed between the blocker plate 116 and the faceplate 118. The blocker plate 116 includes apertures 117 and the faceplate 118 includes apertures 119 through which processing gases flow into the processing volume 108. The plurality of apertures 117 of the blocker plate 116 allows for fluid distribution between the plenum 124 and the plenum 125. The blocker plate 116 is configured to disperse the gas mixture from center to edge before it is introduced to the plenum 125. The plenum 125 enables gas mixture transfer to a processing volume 108 defined between the faceplate 118 and the substrate support assembly 126 through a plurality of apertures 119 formed through the faceplate 118. Further, the gas mixture is ionized to form plasma in the processing volume 108.

The lid assembly 110 further includes a central conduit 138. The central conduit 138 passes through the gas box 114. For example, the central conduit 138 is formed through the lid 106 and the gas box 114 and opens into the plenum 124. The central conduit 138 is configured to provide one or more process gases to the plenum 124 from the gas supply system 140.

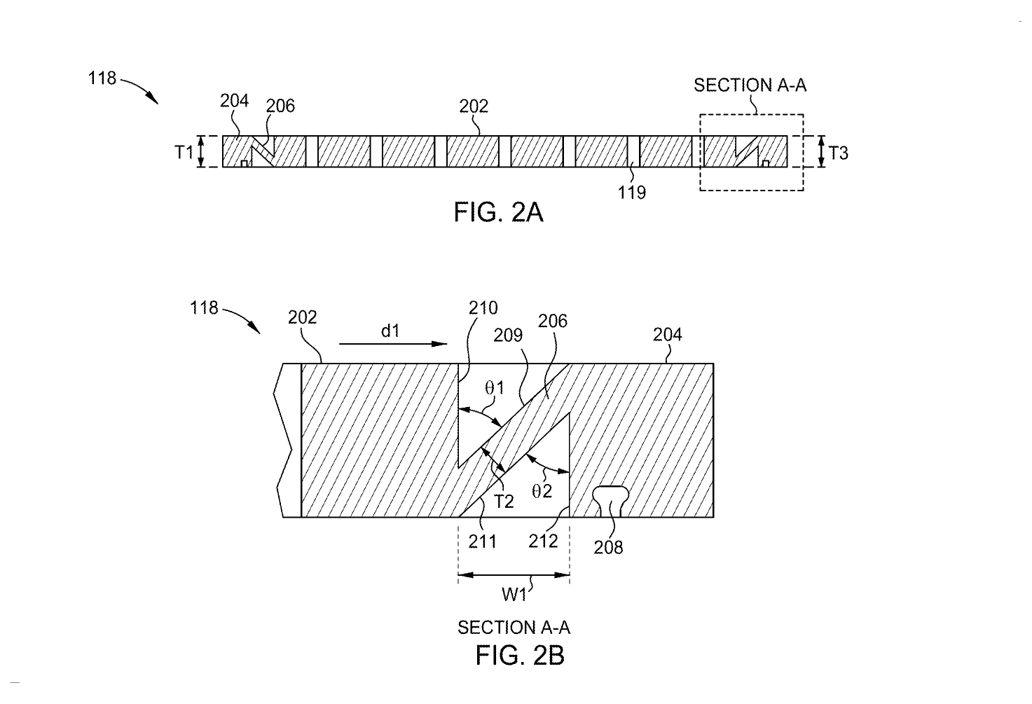

The faceplate 118 may be comprised of a conductive material. For example, the faceplate 118 may be comprised of aluminum or an aluminum alloy. Optionally, the faceplate 118 may include a passivation layer or other protective coating thereon. Additionally, or alternatively, the faceplate 118 may be comprised of other conductive materials. The faceplate 118 includes a mounting ring 141. The mounting ring 141 is circular and positioned around the circumference of the faceplate 118. Further, the mounting ring 141 may be used to mount the faceplate 118 within the lid assembly 110. It is contemplated that the mounting ring may be an integral component of the either the faceplate 118 and/or the blocker plate 116. For example, the mounting ring 141 may be coupled to the blocker plate 116, or another element of the lid assembly 110. The geometry of the faceplate 118 is described in greater detail below in the corresponding description for FIGS. 2A- 3.

The faceplate 118 may be coupled to a power supply 142. The power supply 142 may be an RF generator and may be configured to generate DC power, pulsed DC power, and pulsed RF power. For example, the power supply 142 may drive the faceplate 118 with RF power having a frequency in a range of about 13 MHz to about 60 MHz. Alternatively, frequencies lower than 13 MHz and greater than 60 MHz may be utilized.

During processing, in a plasma-enhanced processing chamber, a plasma is formed in the processing volume 108 from a precursor gas mixture provided through the central conduit 138 via gas supply system 140. The plasma may be formed by capacitive means, and may be energized by coupling RF power into the precursor gas mixture via the power supply 142 and the power supply 150. The RF power may be a dual-frequency RF power that has a high frequency component and a low frequency component. The RF power is typically applied at a power level between about 50 W and about 2500 W, which may be all high-frequency RF power, for example at a frequency in a range of about 13 MHz to 60 MHz. Alternatively, the RF power may be a mixture of high-frequency power and low frequency power, for example at a frequency of about 300 kHz. Upon energizing a plasma in the processing volume 108, a potential difference is established between the plasma and the electrode 134 and/or the faceplate 118. It is contemplated that aspects of the disclosure are beneficial to process chambers which do not utilize a plasma environment for processing, such as thermal process chambers.

A controller 190 is coupled to the process chamber 100. The controller 190 includes a central processing unit (CPU) 192, a memory 194, and support circuits 196. The controller 190 is utilized to control the operation of the process chamber 100. For example, the controller 190 may control the operation of the gas supply system 140 and/or the power supplies 142, 150 and 152.

The CPU 192 may be of any form of a general purpose computer processor that can be used in an industrial setting. The software routines can be stored in the memory 194, such as random access memory, read only memory, floppy or hard disk drive, or other form of digital storage. The support circuits 196 are coupled to the CPU 192 and may comprise cache, clock circuits, input/output subsystems, power supplies, and the like. The software routines, when executed by the CPU 192, transform the CPU 192 into a specific purpose computer (controller) 190 that controls the process chamber 100 such that the processes are performed in accordance with the present disclosure. The software routines may also be stored and/or executed by a second controller (not shown) that is located remotely from the chamber.

FIG. 2A is a schematic illustration of a cross-section of the faceplate 118 shown in FIG. 1, according to one or more embodiments. The faceplate 118 is formed of a material including a metal, such as aluminum. The faceplate includes an inner section 202, an outer section 204 surrounding the inner section 202, and a thermal expansion section 206 located between and coupling the inner section 202 and the outer section 204. The inner section 202 includes the apertures 119 which allow processing gases flow from the plenum 125 into the processing volume 108. The apertures 119 are oriented orthogonal to a plane of the faceplate 118, but other orientations are also contemplated. The inner section 202 of the faceplate 118 has an inner thickness T1 less than 25mm, such as an inner thickness T1 within a range of about 5 mm to about 12 mm. The diameter of the inner section 202 is designed to ensure an even distribution of a precursor material onto the substrate 101. For example, the diameter of the inner section 202 is within a range of about 300 mm to about 400 mm such as about 350 mm.

The outer section 204 has a ring shape and surrounds the inner section 202 of the faceplate 118. The outer section 204 is supported by the chamber body 102 and the mounting ring 141. The outer section 204 is restrained between the chamber body 102 and the mounting ring 141 by friction between the outer section 204 and the chamber body 102 and mounting ring 141. The outer section 204 of the faceplate 118 has an outer thickness T3 less than 25mm, such as an outer thickness T3 within a range of about 5 mm to about 12 mm. It is contemplated that the outer thickness T3 and the inner thickness T1 are the same. In in or more embodiments, the outer section 204 is further restrained using vacuum pressure.

The thermal expansion section 206 connects the inner section 202 and the outer section 204. The inner section 202, the outer section 204, and the thermal expansion section 206 are all part of a monolithic body that forms the faceplate 118. Section A-A of the cross section of the faceplate 118 comprises the outer edge of the inner section 202, as well as outer section 204 and the thermal expansion section 206.

FIG. 2B is an enlarged schematic illustration of section A-A of the faceplate 118 shown in FIG. 2A, according to one or more embodiments. The outer section 204 includes a seal cavity 208 configured to retain a seal such as an O-ring. The O-ring helps provide a seal between the chamber body 102 and the faceplate 118, to help ensure that the processing volume 108 isolated. The thermal expansion section 206 includes an angled connecting member that connects the inner section 202 to the outer section 204. The thermal expansion section 206 has a middle thickness T2 within a range of about 1mm to about 2mm. The inner thickness T1 of the inner section 202 and the outer thickness T3 of the outer section 204 are greater than the middle thickness T2 of the thermal expansion section 206. The thermal expansion section 206 helps prevent the inner section 202 from buckling during a deposition process, and thus the faceplate 118 maintains a more planar shape, improving process uniformity. The thermal expansion section has a width W1. The width W1 is defined by the distance between the outer diameter of the inner section 202 and an inner diameter of the outer section 204. The width W1 is from about 1mm to about 10 mm.

During the deposition process the inner section 202 of the faceplate 118 absorbs energy (such as thermal energy) generated in the processing volume. This increase in energy causes an increase in the temperature of the inner section 202, which causes the inner section 202 to expand in direction d1. As the inner section 202 expands, the thermal expansion causes section 206 to deform (such as compress). For example, if the temperature of the inner section 202 is increased to a temperature of at least 200 degrees Celsius, then the inner section 202 will expand in direction d1 about 1mm. This will cause the thermal expansion section 206 to deflect as the thermal expansion section 206 is the thinnest part of the faceplate 118, and is therefore the first area in the faceplate 118 that will deform. The deflection of the thermal expansion section 206 allows the inner section 202 to expand outward in direction d1 without buckling due to the thermal expansion, and planarity of the faceplate 118 is maintained. Therefore, because the inner section 202 is able to expand without buckling, the inner section 202 of the faceplate 118 is able to have a relatively low inner thickness T1 with a range of about 5mm to about 12mm. When the inner section 202 decreases in temperature, the inner section 202 contracts back to its original diameter and pulls the thermal expansion section 206 back into its original shape before the deposition process. Thus, unexpectedly, a planar configuration of the faceplate 118 is maintained by thinning a portion of the faceplate located between the inner section 202 and the outer section 204.

In addition to allowing the inner section 202 to expand radially outward, the thermal expansion section 206 also acts as a thermal choke. The thickness T2 is less than the thickness T1 of the inner section 202 of the faceplate 118. The lesser thickness of the thermal expansion section 206 prevents heat from conducting from the inner section 202, through the thermal expansion section 206, to the outer section 204. Therefore, the lesser thickness T2 of the thermal expansion section T2 prevents the increased temperature of the inner section 202 from spreading to the outer section 204. The thermal choke allows for a more uniform temperature across the inner section 202 which increases the deposition quality during the deposition process.

The reduced thickness T1 of the faceplate 118 allows for the apertures 119 to be drilled in a single drill pass. Therefore, the time and cost of manufacturing the faceplate 118 is decreased due to the decreased thickness T1 of the faceplate 118.

A first angle Θ1 of the thermal expansion section 206 is defined by a first surface 209 of the thermal expansion section 206 and a first sidewall 210 inner section 202. A second angle Θ2 of the thermal expansion section 206 is defined by a second surface 211 of the thermal expansion section 206 located opposite the first surface 209, and a second sidewall 212 of the outer section 206. In one or more embodiments, the first angle Θ1 and the second angle Θ2 have the same magnitude because the thermal expansion section 206 is substantially planar. However, it is contemplated that the thermal expansion section 206 may be curved, or may have a non-uniform (e.g., increasing or decreasing) thickness. Therefore, in in some embodiments the first angle Θ1 and the second angle Θ2 have the may have differing magnitudes. Angles Θ1, Θ2 can be any angle within a range of about 0 degrees and about 180 degrees such as within a range of about 5 degrees to about 175 degrees, such as within a range of about 20 degrees to about 160 degrees, such as within a range of about 40 degrees to about 140 degrees, such as within a range of about 45 degrees to about 135 degrees.

Although the thermal expansion section 206 is shown connecting the lower surface of the inner section 202 with the upper surface of the outer section 204 it should be understood that the thermal expansion section 206 is depicted this way for illustrative purposes and the thermal expansion section 206 can connect the inner section 202 to the outer section 204 in any manner For example, the thermal expansion section 206 can connect the top surface of the inner section 202 to the bottom surface of the outer section 204 or the thermal expansion section 206 can connect the middle of the inner section 202 to the middle of the outer section 204.

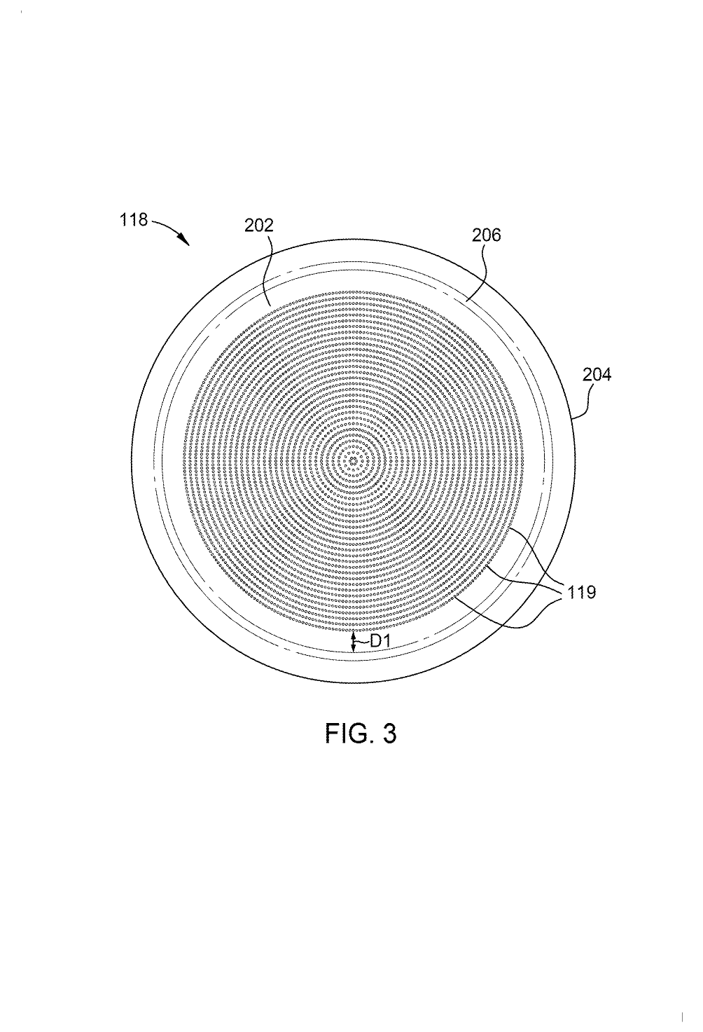

FIG. 3 is a schematic top view of the faceplate 118 shown in FIG. 2A, according to one or more embodiments. The apertures 119 are drilled throughout in the inner section 202 to ensure that the precursor gases get evenly distributed across the substrate 101 during deposition. The apertures 119 extend from the center of the inner section 202 to a distance D1 from the outer diameter of the inner section 202. The distance D1 is from about 1 mm to about 2 mm.

Benefits of the present disclosure include a thinner faceplate 118, deceased buckling of the faceplate 118, decreased cost in manufacturing the faceplate 118; increased efficiency in manufacturing the faceplate 118; increased temperature uniformity across the faceplate 118, increased deposition uniformity across the substrate 101, and improved substrate processing performance, among other benefits.

It is contemplated that one or more aspects disclosed herein may be combined. As an example, one or more aspects, features, components, operations and/or properties of the processing chamber 100, the faceplate 118, the apertures 119, the inner section 202, the outer section 204, the thermal expansion section 206, and/or the seal cavity 208 may be combined. For example, it is contemplated that the blocker plate 116 may also similarly include a thermal expansion section. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A faceplate for a process chamber, the faceplate comprising:
an inner section, comprising a plurality of apertures;
an outer section having a ring shape, the outer section surrounding the inner section; and
a thermal expansion section having a thickness less than a thickness of the inner section and a thickness the outer section, the thermal expansion section connecting the inner section and the outer section, wherein the thermal expansion section is configured to deform when the inner section expands.

2. The faceplate of claim 1, wherein the thickness of the inner section and the outer section of the faceplate is less than 25 mm.

3. The faceplate of claim 2, wherein the thickness of the inner section and the outer section of the faceplate is within a range of about 5 mm to about 12 mm.

4. The faceplate of claim 1, wherein the thermal expansion section has a thickness within a range of about 1mm to about 2mm.

5. The faceplate of claim 1, wherein the faceplate comprises a monolithic body formed of a material comprising aluminum.

6. The faceplate of claim 1, wherein the inner section has a diameter within a range of about 300mm to about 400mm.

7. The faceplate of claim 6, wherein the outer section comprises a seal cavity.

8. A lid assembly for a process chamber, the lid assembly comprising:
a gas box;
a gas conduit passing through the gas box;
a blocker plate coupled to the gas box; and
a faceplate comprising:
an inner section, comprising a plurality of apertures;
an outer section having a ring shape; and
a thermal expansion section having a thickness less than a thickness of the inner section and a thickness the outer section, the thermal expansion section connecting the inner section and the outer section, wherein the thermal expansion section is configured to deform when the inner section expands.

9. The lid assembly of claim 8, wherein the thickness of the inner section and the outer section of the faceplate is less than 25 mm.

10. The lid assembly of claim 9, wherein the thickness of the inner section and the outer section of the faceplate is within a range of about 5 mm to about 12 mm.

11. The lid assembly of claim 8, wherein the thermal expansion section has a thickness within a range of about 1mm to about 2mm.

12. The lid assembly of claim 8, wherein the faceplate comprises a monolithic body formed of a material comprising aluminum.

13. The lid assembly of claim 8, wherein the inner section has a diameter within a range of about 300mm to about 400mm.

14. The lid assembly of claim 8, wherein the thermal expansion section has a width from about 1 mm to about 10 mm.

15. A processing chamber comprising:
a substrate support assembly disposed within a processing volume of the process chamber;
a chamber wall; and
a lid assembly coupled to the chamber wall, the lid assembly comprising:
a blocker plate; and
a faceplate coupled to the blocker plate, the faceplate comprising:
an inner section, comprising a plurality of apertures;
an outer section having a ring shape, the outer section coupled to the chamber wall; and
a thermal expansion section having a thickness less than a thickness of the inner section and a thickness the outer section, the thermal expansion section connecting the inner section and the outer section, wherein the thermal expansion section is configured to deform when the inner section expands.

16. The processing chamber of claim 15, wherein the thickness of the inner section and the outer section of the faceplate is less than 25 mm.

17. The processing chamber of claim 16, wherein the thickness of the inner section and the outer section of the faceplate is within a range of about 5 mm to about 12 mm.

18. The processing chamber of claim 15, wherein the thermal expansion section has a thickness within a range of about 1mm to about 2mm.

19. The processing chamber of claim 15, wherein the faceplate comprises a monolithic body formed of a material comprising aluminum.

20. The lid assembly of claim 15, wherein outer section of the faceplate is restrained to the chamber wall using a vacuum pressure.
